(19) United States
(12) Patent Application Publication
(10) Pub. No.: US 2012/0108002 A1
(43) Pub. Date: May 3, 2012

(54) APPARATUS, METHOD AND SYSTEM FOR DEPOSITING LAYER OF SOLAR CELL

(75) Inventors: Jeongchul LEE, Daejeon (KR); Jinsoo SONG, Daejeon (KR); Junsik CHO, Daejeon (KR); Sanghyun PARK, Daejeon (KR)

(73) Assignee: Korea Institute of Energy Research, Daejeon (KR)

(21) Appl. No.: 13/244,598

(22) Filed: Sep. 25, 2011

(30) Foreign Application Priority Data
Oct. 28, 2010 (KR) 10-2010-0105758

(51) Int. Cl. H01L 31/18; C23C 16/455; C23C 16/458; C23C 16/22

(52) U.S. Cl. 438/96; 118/722; 118/724; 118/723 R; 257/E31.048

(57) ABSTRACT

The apparatus for thin film deposition for solar cells includes multiple unit chambers divided by a substrate as a boundary, a deposition gas injecting unit injecting deposition gases independently to each of the multiple unit chambers, and a decomposition unit in each of the multiple unit chambers to decompose the deposition gases, wherein both surfaces of the substrate each are exposed to the multiple unit chambers. The apparatus and the method for producing solar cells allow deposition on both surfaces of a substrate while the substrate is fixed without any rotation. Therefore, the number of processing units required for carrying out deposition is decreased, thereby providing high cost efficiency. Further, it results in a decrease in time during which the substrate is exposed to the exterior, thereby minimizing contamination of the surfaces of the substrate. As a result, it is possible to provide solar cells having excellent reliability.

### CROSS-REFERENCE TO RELATED APPLICATIONS

This application claims priority under 35 U.S.C. §119 to Korean Patent Application No. 10-2010-0105758, filed on Oct. 28, 2010, in the Korean Intellectual Property Office, the disclosure of which is incorporated herein by reference in its entirety.

### TECHNICAL FIELD

The following disclosure relates to an apparatus, method and system for thin film deposition for solar cells. More particularly, the following disclosure relates to a novel apparatus, method and system for thin film deposition for solar cells, which allow deposition on both surfaces of a substrate while the substrate is fixed without any rotation, thereby providing high cost efficiency, and minimize contamination of the surfaces of the substrate by reducing time during which the substrate is exposed to the exterior.

### BACKGROUND

Recently, due to the oil price increase and other problems, including environmental pollution, fossil fuel depletion, treatment of waste from nuclear power generation and selection of the location of a new power plant, much attention has been given to novel/regenerated energy. Particularly, many attempts have been made to develop solar cells as pollution-free energy resources. The term ‘solar cell’ means a system capable of converting light energy into electric energy by using a so-called photovoltaic effect. Such solar cells are classified, depending on their constitution, into silicon solar cells, thin film solar cells, dye sensitized solar cells, organic polymer solar cells, etc. Such solar cells are independently used as main power sources for electronic watches, radios, unmanned light houses, artificial satellites, rockets, etc. Additionally, they are linked to commonly used AC power source systems so that they may be used as supplementary power sources thereof. More recently, as alternative energy has been increasingly in demand, solar cells have been spotlighted. It is important for such solar cells to realize increased conversion efficiency related to the conversion ratio of incident sunlight into electric energy. Many attempts have been made to increase the conversion efficiency. Particularly, active research and development have been conducted to increase the conversion efficiency by incorporating thin films having a high light absorption coefficient into solar cells.

Meanwhile, solar cells using sunlight may be classified, depending on the properties of p regions and n regions used for p-n junction, into homojunction solar cells and heterojunction solar cells. Among them, heterojunction solar cells have different crystal structures or a structure including different materials bonded to each other.

One of such heterojunction solar cells is a heterojunction with intrinsic thin film (HIT) solar cell available from Sanyo Co., Japan. The most significant characteristic of such HIT solar cells is that an intrinsic amorphous silicon layer is interposed between an n-type silicon substrate and a p-type amorphous silicon layer. The intrinsic amorphous silicon layer is a substantially pure amorphous silicon layer in which the number of electrons is the same as that of holes. It is possible to prevent electron-hole recombination, caused by interfacial defects between a crystalline silicon substrate and an amorphous silicon layer or other reasons by using the intrinsic amorphous silicon layer.

Recently, the above-mentioned HIT structures have been realized on both surfaces of a substrate to improve the efficiency of a solar cell. However, in this case, deposition on one surface of the substrate is merely carried out in one chamber. Thus, two chambers are required to deposit a layer on each of the two surfaces of the substrate. Moreover, since the substrate is rotated to turn it upside down, there are problems in that the substrate may be damaged mechanically and an increase in the number of processing operations may result in increased pollution. Therefore, because the apparatus and method for producing solar cells according to the related art allow deposition on a single surface in one processing chamber, an increase in the number of processing operations leads to an increase in the number of apparatuses required for producing solar cells. Further, such an increased number of processing operations may degrade reliability of producing solar cells.

### SUMMARY

An embodiment of the present disclosure is directed to providing an apparatus and system for thin film deposition for solar cells, which allow deposition on both surfaces of a substrate while the substrate is fixed without any rotation, thereby providing high cost efficiency, and minimize contamination of the surfaces of the substrate by reducing time during which the substrate is exposed to the exterior, as well as a method for producing solar cells using the same.

Another embodiment of the present disclosure is directed to providing a method for producing heterojunction solar cells, which provides high cost efficiency and minimizes contamination of the surface of a substrate, as well as a heterojunction solar cell obtained by the same.

Other features and aspects will be apparent from the following detailed description and the claims.

### BRIEF DESCRIPTION OF THE DRAWINGS

The above and other aspects, features and advantages of the disclosed exemplary embodiments will be more apparent from the following detailed description taken in conjunction with the accompanying drawings in which:

FIG. 1 is a schematic view showing an apparatus for thin film deposition for solar cells according to an embodiment.

FIGS. 2 and 3b are schematic views showing an apparatus for thin film deposition for solar cells, wherein a substrate is disposed horizontally or vertically, respectively.

FIG. 4 is a schematic view illustrating a method for depositing thin films on both surfaces of a substrate by using the apparatus as shown in FIG. 2.

FIG. 5 is a schematic view illustrating a process of depositing two layers on both surfaces of a substrate by using the apparatus according to an embodiment.

FIG. 6 is a flow chart of a method for producing solar cells including a depositing process according to an embodiment.

FIG. 7 is a sectional view showing a heterojunction solar cell obtained by the method disclosed herein.

FIG. 8 is a flow chart of the method for producing the heterojunction solar cell as shown in FIG. 7.

FIG. 9 is a schematic view illustrating a process for producing a heterojunction solar cell by using the system for thin film deposition for solar cells according to an embodiment.

FIG. 10 is a sectional view showing a process for thin film deposition for solar cells using the apparatuses A-C as shown in FIG. 9.

### DETAILED DESCRIPTION OF EMBODIMENTS

The advantages, features and aspects of the present disclosure will become apparent from the following description of the embodiments with reference to the accompanying drawings, which is set forth hereinafter. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof.

In one aspect, there are provided an apparatus for depositing thin films on both surfaces of a substrate for solar cells in a single chamber, and a method for producing solar cells using the same.

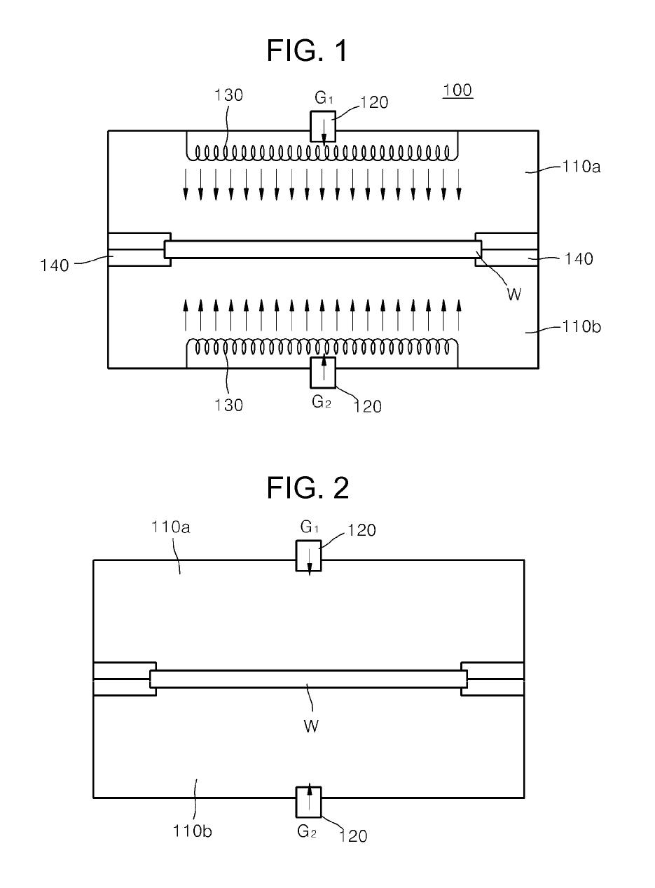

FIG. 1 is a schematic view showing an apparatus for thin film deposition for solar cells in accordance with an embodiment.

Referring to FIG. 1, the apparatus for thin film deposition for solar cells according to an embodiment, more particularly a chamber 100 of the apparatus includes multiple unit chambers. In FIG. 1, the apparatus includes two unit chambers 110a, 110b. In addition, deposition gas injecting units 120 are provided in the two unit chambers 110a, 110b, and reaction gases G₁, G₂ are introduced through the deposition gas injecting units 120 for carrying out deposition. Therefore, the two unit chambers are independently provided with the deposition gas injecting units 120 for injecting gases to both sides of a substrate. In this manner, the deposition gas injecting units may serve as paths through which the same type or different types of deposition gases are injected to the two unit chambers 110a, 110b. The deposition gases may also be injected from the lateral side of the substrate as well as the vertical side thereof. In this case, a nozzle type deposition gas injecting units 120 may be used. In the case of a large-area substrate, the deposition gas injecting units may be provided in the form of shower nozzles, because uniform dispersion over the whole substrate is very important.

As described above, the apparatus for thin film deposition for solar cells according to an embodiment uses the substrate W as a boundary defining the two unit chambers, so that both surfaces of the substrate W are exposed to both unit chambers 110a, 110b. In other words, the apparatus for thin film deposition for solar cells disclosed herein uses the substrate W as a part of the partition of the two unit chambers 110a, 110b, which may be divided by the substrate W and a supporting member 140 holding the substrate.

The apparatus may further include a decomposition unit 130 by which the same type or different types of deposition gases G₁, G₂ injected to the two unit chambers 110a, 110b are decomposed. The decomposition unit 130 is independently provided in each of the two unit chambers 110a, 110b, and is spaced apart from the substrate W positioned at the boundary of the two unit chambers by a predetermined distance. The deposition gas decomposition unit 130 decomposes the deposition gases injected to the unit chambers so as to allow deposition of a thin film on the surface of the substrate W. In FIG. 1, a hot wire is used as the deposition gas decomposition unit 130. However, a plasma generating unit using RF or microwaves may also be used as the deposition gas decomposition unit 130 within the scope of the present disclosure.

According to an embodiment, the deposition gases may include silane and hydrogen for forming silicon thin films, and may further include suitable dopant gases depending on the particular type of the thin film to be deposited. Further, any gases decomposed by the deposition gas decomposition unit 130 may be included in the deposition gases used herein as gases for depositing elementary layers, such as a transparent electrode material, of a solar cell.

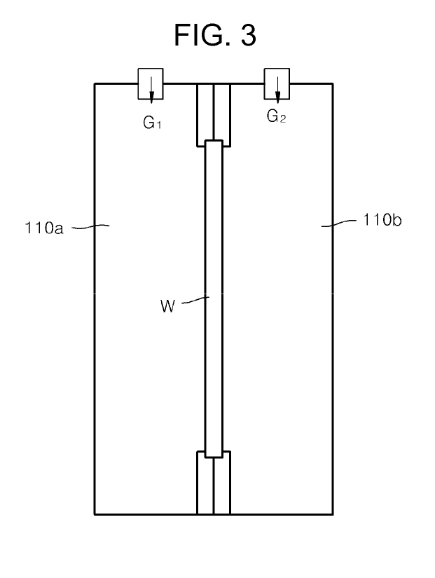

FIGS. 2 and 3 are schematic views showing an apparatus for thin film deposition for solar cells, wherein a substrate is disposed horizontally or vertically, respectively.

Referring to FIGS. 2 and 3, two unit chambers 110a, 110b are divided horizontally or vertically and the boundary surface of the unit chambers 110a, 110b is provided partially or totally by a substrate W on which deposition is carried out. Therefore, both surfaces of the substrate defining the unit chambers 110a, 110b are independently exposed to each unit chamber.

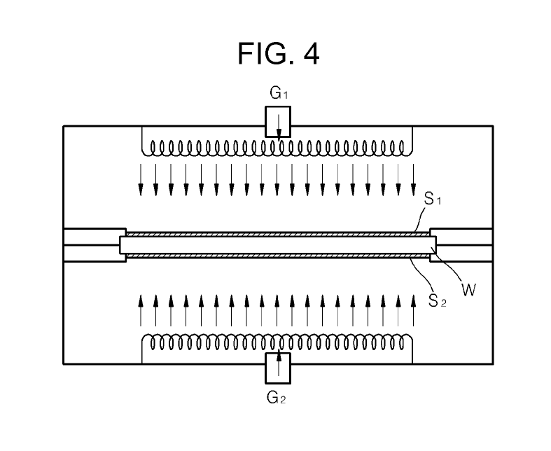

FIG. 4 is a schematic view illustrating a method for depositing thin films on both surfaces of a substrate by using the apparatus as shown in FIG. 2.

Referring to FIG. 4, a part of the boundary defining two unit chambers 110a, 110b is a substrate W on which deposition is carried out. The substrate W is coupled with supporting members 140 that hold the ends of the substrate to fix and support the whole substrate.

The deposition gases G₁, G₂ injected through the deposition gas injecting units 120 are decomposed individually by decomposition units 130, and then deposited on the top surface and the bottom surface of the substrate, thereby forming thin films S₁, S₂. Particularly, injection of gases and deposition of thin films may be carried out simultaneously in both unit chambers. However, injection of gases and deposition of thin films may also be carried out sequentially. It is to be noted that the apparatus and method for thin film deposition for solar cells disclosed herein require no rotating unit and rotating process to turn the substrate upside down, thereby minimizing contamination of the substrate and decreasing mechanical load on the substrate.

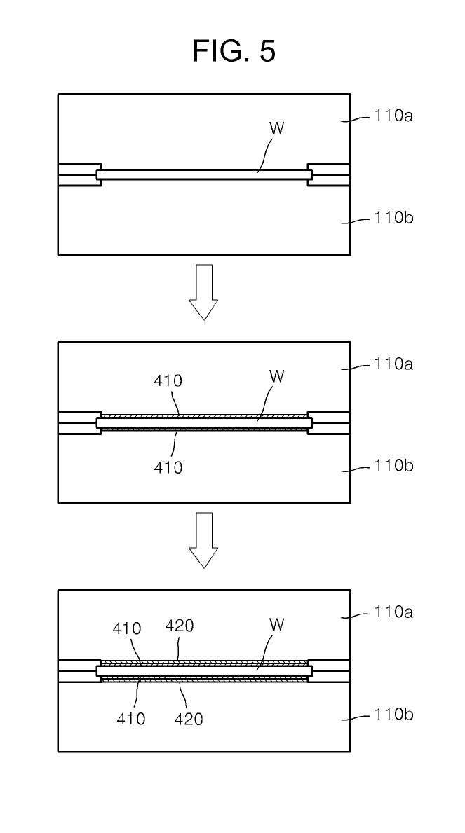

FIG. 5 is a schematic view illustrating a process of depositing two layers on both surfaces of a substrate by using the apparatus according to an embodiment.

Referring to FIG. 5, a first thin film 410 is deposited on each of the two surfaces of the bare substrate W. Herein, since the apparatus and method disclosed herein are used to carry out such thin film deposition on both surfaces, any rotating unit by which the substrate is turned upside down and any rotating process using the same are not required.

Next, the substrate having the first thin film 410 deposited on each of the two surfaces is transferred to another deposition apparatus and another process for carrying out deposition on both surfaces of the substrate. Herein, a second thin film 420 is deposited on the first thin film 410. Similarly, the second thin film 420 is deposited on each of the two surfaces of the substrate. However, deposition of both surfaces of the substrate may be carried out twice or more in the same chamber within the scope of the present disclosure.

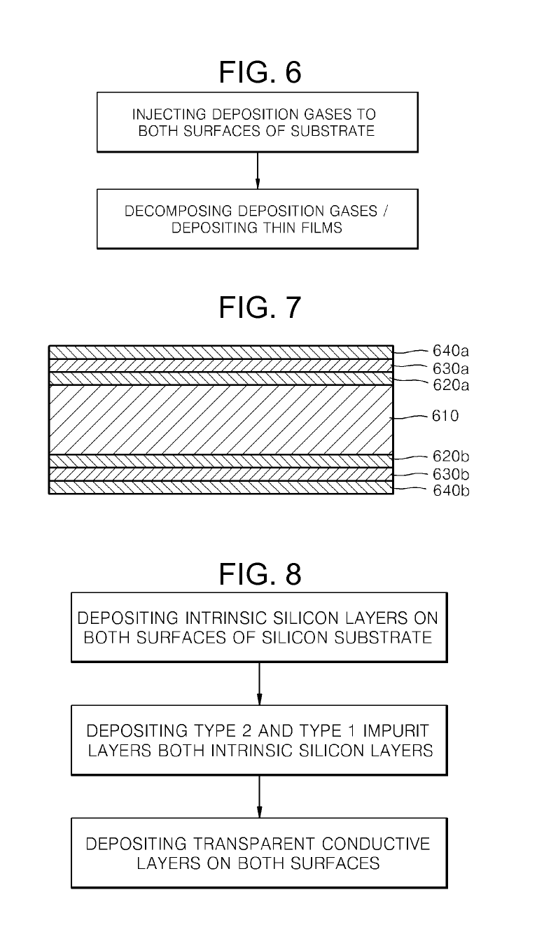

FIG. 6 is a flow chart of a method for producing solar cells including a depositing process according to an embodiment.

Referring to FIG. 6, the method for producing solar cells disclosed herein includes injecting deposition gases to both surfaces of a solar cell substrate, decomposing the injected deposition gases by a separate decomposition unit, and depositing the decomposed reaction gases on the substrate to form thin films on the substrate.

Herein, the substrate serves partially or totally as a boundary of unit chambers to which the deposition gases are injected. In other words, the unit chambers are divided by the substrate as a boundary. The deposition gases injected to the two unit chambers divided by the substrate serving partially or totally as a boundary may be injected to each unit chamber in an independent manner. More particularly, the same type of deposition gases or different types of deposition gases may be injected to the two unit chambers simultaneously or sequentially. The injection rate and pressure may be controlled independently in each chamber.

The apparatus and method for thin film deposition for solar cells disclosed herein may be used to produce heterojunction solar cells. Hereinafter, the method for producing heterojunction solar cells will be described in more detail with reference to the accompanying drawings.

FIG. 7 is a sectional view showing a heterojunction solar cell obtained by the method disclosed herein.

Referring to FIG. 7, a central silicon substrate, particularly a silicon substrate 610 doped with type 1 impurity such as n-type impurity is provided. Intrinsic silicon layers 620a, 620b are deposited on both surfaces of the silicon substrate 610, and two silicon layers 630a, 630b doped with n-type and p-type impurities (type 1 and type 2 impurities) are further deposited on the intrinsic silicon layers 620a, 620b. Two silicon layers 630a, 630b doped with different types of impurities may be deposited by the apparatus disclosed herein (i.e. apparatus for thin film deposition including two unit chambers divided by a substrate) within the scope of the present disclosure.

Then, transparent conductive electrode layers, such as indium tin oxide (ITO) layers 640a, 640b are deposited on the silicon layers 630a, 630b, and the transparent conductive electrode layers are deposited on both sides of the central substrate 610. Therefore, the transparent conductive electrode layers 640a, 640b may be formed in a single apparatus by the apparatus for thin film deposition disclosed herein.

When the solar cell as shown in FIG. 7 is produced by using the apparatus (chamber) according to the related art, deposition processes may be required six times on both surfaces of the substrate. Thus, at least six deposition chambers are required. Particularly, a deposition process using a vacuum chamber (plasma-enhanced chemical vapor deposition, PECVD) requires high cost due to the use of six deposition chambers. On the contrary, when using the apparatus disclosed herein, deposition processes are required only three times to provide the solar cell having the same structure as described above. Therefore, the apparatus and method for thin film deposition for solar cells disclosed herein require only about one half of the number of processes and apparatuses required for producing solar cells, particularly heterojunction solar cells, according to the related art. As a result, the apparatus and method disclosed herein are cost- and time-efficient.

FIG. 8 is a flow chart of the method for producing the heterojunction solar cell as shown in FIG. 7.

Referring to FIG. 8, intrinsic silicon layers 620a, 620b are deposited first on both surfaces of the silicon substrate 610, type 1 and type 2 impurity layers 630a, 630b are further deposited on the intrinsic silicon layers 620a, 620b in the same chamber, and then transparent conductive layers 640a, 640b are deposited on the type 1 and type 2 impurity layers 630a, 630b. Each of the depositing processes may be carried out in a continuous deposition system (including a series of deposition apparatuses). Hereinafter, the system will be explained in more detail.

In another aspect, there is provided a system for thin film deposition including the apparatuses for thin film deposition linked to each other continuously. The system includes a plurality of the apparatuses spaced apart from each other by a predetermined distance. The system may further include a transfer unit between one apparatus and the adjacent apparatus to transfer the substrate after carrying out deposition on both surfaces thereof. The substrate is subjected sequentially to depositing processes on both surfaces thereof through each of the apparatuses in the system disclosed herein, while not causing the substrate to be turned upside down.

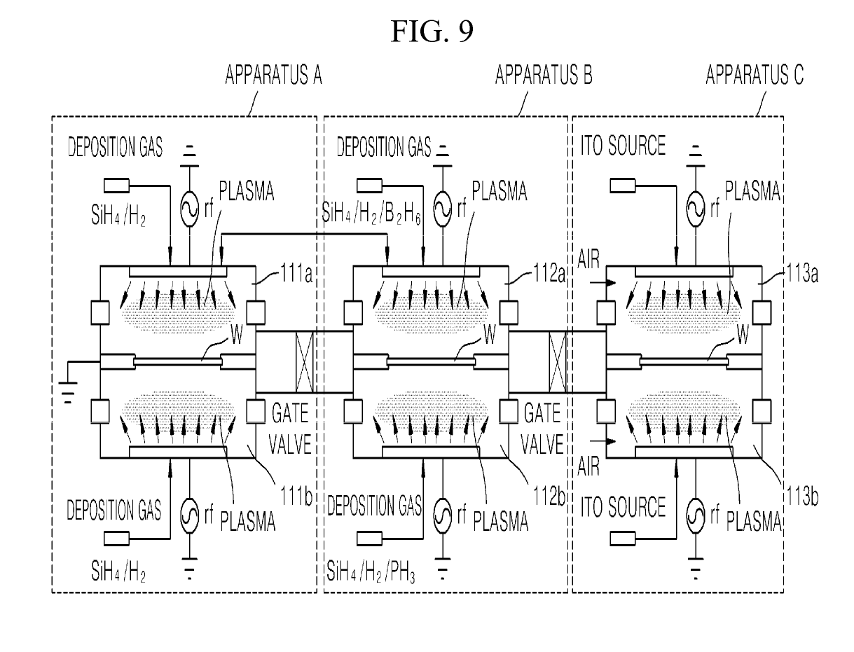

The above-described system is used to produce a heterojunction solar cell and a flow chart for the production of a heterojunction solar cell is shown in FIG. 9.

FIG. 9 is a schematic view illustrating a process for producing a heterojunction solar cell by using the system for thin film deposition for solar cells according to an embodiment.

Referring to FIG. 9, in apparatus A, silane/hydrogen (SiH₄/H₂) deposition gases introduced thereto are decomposed by using RF plasma. The deposition gases are injected to the substrate W along the vertical direction and then diffused through a shower nozzle. Such deposition gas injection and plasma generation are carried out both in an upper unit chamber 111a and a lower unit chamber 111b of the substrate.

After carrying out deposition of both surfaces of the substrate in apparatus A, the gases inside the chambers are discharged and a gate valve is opened. After opening the gate valve, the substrate W is transferred to apparatus B. The substrate W transferred to apparatus B forms a boundary between an upper unit chamber 112a and a lower unit chamber 112b. Then, each of deposition gases containing different dopant gases (B₂H₆, PH₃) is independently injected to the upper chamber 112a and the lower chamber 112b. The deposition gases introduced to the chambers are decomposed in each of the unit chambers 112a, 112b, so that they are deposited on the silicon layers of the substrate. Then, an ITO source is subjected to plasma decomposition through apparatus C and deposited on both surfaces of the substrate. Although the system according to the above-described embodiment includes decomposing the deposition gases by using RF plasma, the deposition gases may also be decomposed, for example, by hot wires within the scope of the present disclosure.

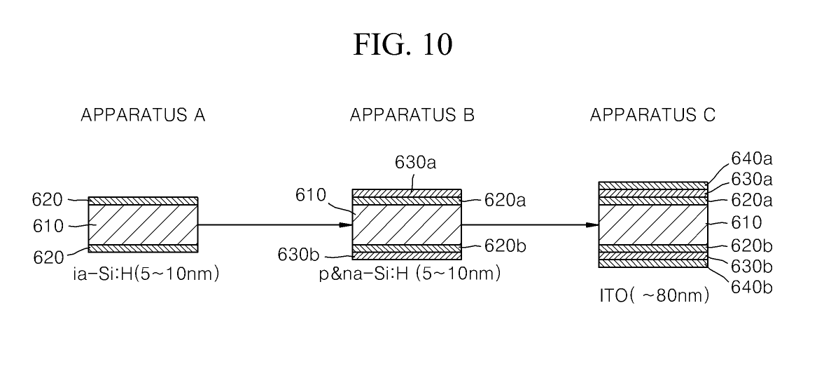

FIG. 10 is a sectional view showing a process for thin film deposition for solar cells using the apparatuses A-C as shown in FIG. 9.

Referring to FIG. 10, intrinsic silicon layers 620 are deposited on both surfaces of a substrate in apparatus A, and silicon layers 630a, 630b doped with n-type and p-type impurities, respectively, are deposited thereon in apparatus B. Then, ITO electrode layers 640a, 640b are further deposited on both surfaces of the substrate in apparatus C. Deposition of each type of layer is carried out on both surfaces of the substrate by using the apparatus disclosed herein.

The apparatus for thin film deposition for solar cells and the method for producing solar cells disclosed herein allow deposition on both surfaces of a substrate while the substrate is fixed without any rotation. Therefore, as compared to the related art that allows deposition of a single layer on one surface of a substrate, the number of processing units required for carrying out deposition is decreased significantly, thereby providing higher cost efficiency than the related art. Further, such a decreased number of processing operations results in a decrease in time during which the substrate is exposed to the exterior, thereby minimizing contamination of the surfaces of the substrate. As a result, it is possible to provide solar cells having excellent reliability.

While the present disclosure has been described with respect to the specific embodiments, it will be apparent to those skilled in the art that various changes and modifications may be made without departing from the spirit and scope of the disclosure as defined in the following claims.

What is claimed is:

1. An apparatus for thin film deposition for solar cells, which comprises:
multiple unit chambers divided by a substrate as a boundary;
a deposition gas injecting unit injecting deposition gases independently to each of the multiple unit chambers; and
a decomposition unit provided in each of the multiple unit chambers to decompose the deposition gases introduced to the unit chambers,
wherein both surfaces of the substrate each are exposed to the multiple unit chambers.

2. The apparatus for thin film deposition for solar cells according to claim 1, which comprises two unit chambers divided by the substrate and a supporting member holding the substrate.

3. The apparatus for thin film deposition for solar cells according to claim 2, wherein the decomposition unit is spaced apart from one side of the substrate by a predetermined distance.

4. The apparatus for thin film deposition for solar cells according to claim 3, wherein the decomposition unit is a hot wire or plasma generating unit.

5. The apparatus for thin film deposition for solar cells according to claim 1, wherein the deposition gases include silane and hydrogen and further comprise a dopant gas depending on a thin film to be deposited.

6. A system for thin film deposition for solar cells, which comprises a plurality of the apparatuses for thin film deposition for solar cells according to claim 1, wherein thin film deposition processes are carried out sequentially on the same substrate by the apparatuses.

7. The system for thin film deposition for solar cells according to claim 6, which comprises:
the apparatuses for thin film deposition for solar cells according to claim 1, spaced apart from each other by a predetermined distance; and
a substrate transferring unit passing through the apparatuses for thin film deposition for solar cells.

8. The system for thin film deposition for solar cells according to claim 6, wherein thin films are deposited on both surfaces of the substrate simultaneously or sequentially as deposition processes are carried out by the apparatuses for thin film deposition for solar cells.

9. A method for producing solar cells, comprising:
injecting deposition gases to both surfaces of a solar cell substrate; and
decomposing the deposition gases to deposit thin films on both surfaces of the substrate.

10. The method for producing solar cells according to claim 9, wherein the deposition gases are injected to unit chambers divided by the substrate as a boundary.

11. The method for producing solar cells according to claim 10, wherein the substrate forms a boundary surface of the unit chambers.

12. The method for producing solar cells according to claim 10, wherein the deposition gases are injected independently to each of the unit chambers and the substrate is not rotated during deposition processes.

13. The method for producing solar cells according to claim 12, wherein the substrate is a silicon solar cell doped with type 1 impurity.

14. A method for producing heterojunction solar cells, comprising:
depositing intrinsic amorphous silicon layers on both surfaces of a silicon substrate;
depositing amorphous silicon layers doped with each of type 2 impurity and type 1 impurity on both surfaces of the substrate on which the amorphous silicon layers are deposited; and
depositing transparent conductive electrode layers on the substrate,
wherein said depositing each is carried out by the method as defined in claim 9.

15. The method for producing heterojunction solar cells according to claim 14, wherein said depositing each is carried out by decomposing the deposition gases injected to both surfaces of the substrate by plasma or heat.

16. The method for producing heterojunction solar cells according to claim 15, wherein said depositing each is carried out in a separate apparatus for thin film deposition.
